(19) United States
(12) Patent Application Publication
(10) Pub. No.: US 2025/0255086 A1
(43) Pub. Date: Aug. 7, 2025

(54) DISPLAY APPARATUS

(71) Applicant: Samsung Display Co., LTD., Yongin-si (KR)

(72) Inventors: Soungwook Kim, Yongin-si (KR); Seokgyu Yoon, Yongin-si (KR); Minsoo Choi, Yongin-si (KR); Dongkyu Seo, Yongin-si (KR); Kunwook Cho, Yongin-si (KR)

(21) Appl. No.: 19/020,923

(22) Filed: Jan. 14, 2025

(30) Foreign Application Priority Data
Feb. 2, 2024 (KR) 10-2024-0016915

(51) Int. Cl. H10K 39/34; H10K 30/85; H10K 59/80

(52) U.S. Cl. CPC H10K 39/34; H10K 30/85; H10K 59/80518; H10K 59/80524; H10K 59/876

(57) ABSTRACT

A display apparatus includes: a substrate comprising an emission area and a sensing area; a light-emitting device on the substrate to correspond to the emission area; and a light-receiving device on the substrate to correspond to the sensing area, wherein the light-emitting device comprises a pixel electrode, an emission layer on the pixel electrode, and a counter electrode on the emission layer, and the light-receiving device comprises a sensing electrode, an active layer on the sensing electrode, and the counter electrode on the active layer, wherein the active layer comprises a first layer comprising an electron donor material and a second layer on the first layer and comprising an electron acceptor material, wherein, in a thickness direction of the substrate, a thickness of the first layer is at least a thickness of the second layer.

### CROSS-REFERENCE TO RELATED APPLICATION

The present application claims priority to and the benefit of Korean Patent Application No. 10-2024-0016915, filed on Feb. 2, 2024, in the Korean Intellectual Property Office, the entire disclosure of which is incorporated herein by reference.

### BACKGROUND

### 1. Field

Aspects of one or more embodiments relate to a structure of a display apparatus.

### 2. Description of the Related Art

In general, a display apparatus operates by forming light-emitting devices such as organic light-emitting diodes and thin-film transistors on a substrate and allowing the light-emitting devices to emit light.

For example, each pixel of a display apparatus may include a light-emitting device such as an organic light-emitting diode in which an intermediate layer including an emission layer is located between a pixel electrode and a counter electrode. The display apparatus generally controls whether each pixel emits light or a degree of emission through a thin-film transistor electrically connected to the pixel electrode. Some layers included in the intermediate layer of the light-emitting device may be commonly provided in a plurality of light-emitting devices.

The above information disclosed in this Background section is only for enhancement of understanding of the background and therefore the information discussed in this Background section does not necessarily constitute prior art.

### SUMMARY

Aspects of one or more embodiments include a display apparatus capable of displaying relatively high-quality images and having relatively improved detection performance. However, the embodiments are examples and do not limit the scope of embodiments according to the present disclosure.

Additional aspects will be set forth in part in the description which follows and, in part, will be apparent from the description, or may be learned by practice of the presented embodiments.

According to one or more embodiments, a display apparatus includes a substrate including an emission area and a sensing area, a light-emitting device located on the substrate to correspond to the emission area, and a light-receiving device located on the substrate to correspond to the sensing area, wherein the light-emitting device includes a pixel electrode, an emission layer located on the pixel electrode, and a counter electrode located on the emission layer, and the light-receiving device includes a sensing electrode, an active layer located on the sensing electrode, and the counter electrode located on the active layer, wherein the active layer includes a first layer including an electron donor material and a second layer located on the first layer and including an electron acceptor material, wherein, in a thickness direction of the substrate, a thickness of the first layer is at least a thickness of the second layer.

According to some embodiments, the first layer may include a p-type organic semiconductor, and the second layer may include an n-type organic semiconductor.

According to some embodiments, the thickness of the first layer may be inversely proportional to an absorbance of the first layer.

According to some embodiments, a thickness of the first layer may be in a range of about 200 Å to about 600 Å.

According to some embodiments, the absorbance of the first layer may be about 0.2 to about 0.6.

According to some embodiments, the thickness of the first layer may satisfy Equation 1,

$$T = 120 / a , \qquad Equation 1$$

where T is the thickness of the first layer and a is the absorbance of the first layer.

According to some embodiments, the display apparatus may further include a common layer located between the pixel electrode and the emission layer and between the sensing electrode and the active layer, wherein the common layer includes at least one of a hole injection layer or a hole transport layer.

According to some embodiments, the light-emitting device may further include an optical auxiliary layer located between the common layer and the emission layer, wherein a bottom surface of the emission layer directly contacts a top surface of the optical auxiliary layer.

According to some embodiments, the optical auxiliary layer may be patterned to have a different thickness for each light-emitting device.

According to some embodiments, a bottom surface of the active layer may directly contact a top surface of the common layer.

According to some embodiments, the pixel electrode and the sensing electrode may be reflective electrodes, and the counter electrode may be a transflective electrode or a transmissive electrode.

According to some embodiments, the light-emitting device may have a front resonance structure, and the light-receiving device may have a non-resonance structure in which a resonance phenomenon is neutralized.

According to one or more embodiments, a display apparatus includes a substrate, a light-emitting device located on the substrate and including a pixel electrode, an emission layer located on the pixel electrode, and a counter electrode located on the emission layer, and a light-receiving device located on the substrate and including a sensing electrode, an active layer located on the sensing electrode, and the counter electrode located on the active layer, wherein the light-emitting device and the light-receiving device further include a common layer located between the pixel electrode and the emission layer and between the sensing electrode and the active layer, wherein a bottom surface of the active layer and a top surface of the common layer directly contact each other.

According to some embodiments, the common layer may include at least one of a hole injection layer or a hole transport layer, wherein the common layer is integrally formed over an entire surface of the substrate.

According to some embodiments, the light-emitting device may further include an optical auxiliary layer located between the common layer and the emission layer, wherein a bottom surface of the emission layer directly contacts the optical auxiliary layer.

According to some embodiments, the optical auxiliary layer may be patterned only in the light-emitting device and may not be located in the light-receiving device.

According to some embodiments, the active layer may include a first layer including an electron donor layer and a second layer located on the first layer and including an electron acceptor material, wherein, in a thickness direction of the substrate, a thickness of the first layer is at least a thickness of the second layer.

According to some embodiments, the first layer may include a p-type organic semiconductor, and the second layer may include an n-type organic semiconductor.

According to some embodiments, the thickness of the first layer may be inversely proportional to an absorbance of the first layer.

According to some embodiments, the pixel electrode and the sensing electrode may be reflective electrodes, and the counter electrode may be a transflective electrode or a transmissive electrode.

### BRIEF DESCRIPTION OF THE DRAWINGS

The above and other aspects, features, and characteristics of certain embodiments will be more apparent from the following description taken in conjunction with the accompanying drawings, in which:

FIG. 1 is a plan view schematically illustrating a part of a display apparatus, according to some embodiments;

FIG. 2 is a schematic cross-sectional view illustrating a display apparatus, according to some embodiments;

FIG. 3 is an equivalent circuit diagram illustrating a pixel circuit electrically connected to a light-emitting device and a sensor circuit electrically connected to a light-receiving device of a display apparatus, according to some embodiments;

FIG. 4 is a plan view schematically illustrating a part of a display apparatus, according to some embodiments;

FIG. 5 is a cross-sectional view schematically illustrating a part of a display apparatus, according to some embodiments;

FIG. 6 is a conceptual view schematically illustrating a portion of a display apparatus, according to some embodiments; and

FIG. 7 is a graph comparing external quantum efficiency according to a wavelength between a display apparatus according to a comparative example and a display apparatus according to some embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or any combination of a, b, and/or c.

As the disclosure allows for various changes and numerous embodiments, certain embodiments will be illustrated in the drawings and described in the detailed description. Effects and features of the disclosure, and methods for achieving them will be clarified with reference to embodiments described below in more detail with reference to the drawings. However, the disclosure is not limited to the following embodiments and may be embodied in various forms.

Reference will now be made in more detail to aspects of some embodiments, examples of which are illustrated in the accompanying drawings, and in the drawings, the same elements are denoted by the same reference numerals, and thus a repeated description thereof will be omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be further understood that the terms “comprises” or “comprising” used herein specify the presence of stated features or components, but do not preclude the presence or addition of one or more other features or components.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the disclosure is not limited thereto.

When a certain embodiment may be implemented differently, a specific process order may be different from the described order. For example, two consecutively described processes may be performed substantially at the same time or may be performed in an order opposite to the described order.

It will be understood that when a layer, region, or component is referred to as being “connected,” the layer, the region, or the component may be directly connected or may be indirectly connected with intervening layers, regions, or components therebetween. For example, when layers, regions, or components are referred to as being “electrically connected,” the layers, the regions, or the components may be directly electrically connected, or may be indirectly electrically connected with intervening layers, regions, or components therebetween.

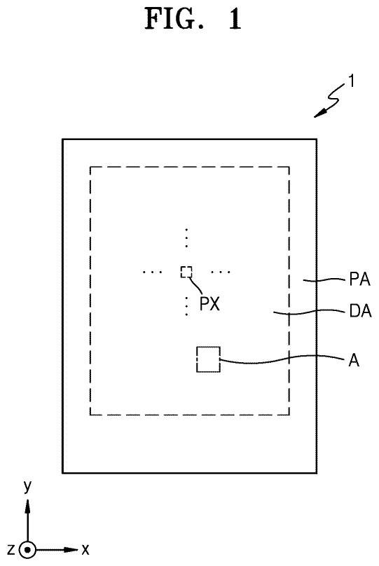

FIG. 1 is a plan view schematically illustrating aspects of a display apparatus, according to some embodiments.

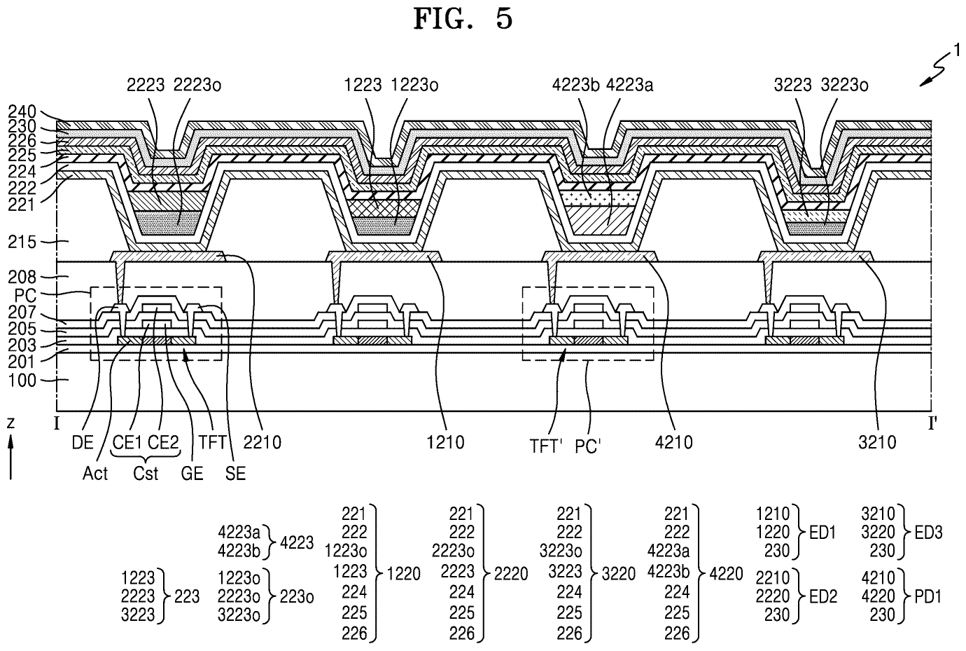

Referring to FIG. 1, a display apparatus 1 may include a display area DA where a plurality of pixels PX are located and a peripheral area PA located outside (e.g., in a periphery or outside a footprint of) the display area DA. For example, the peripheral area PA may entirely surround the display area DA. A substrate 100 (see FIG. 5) included in the display apparatus may include the display area DA and the peripheral area PA. Although FIG. 1 illustrates a single pixel PX, embodiments according to the present disclosure are not limited thereto, and as a person having ordinary skill in the art would appreciate, the display apparatus 1 may include any suitable number of rows and columns of pixels PX according to the design and size of the display area DA.

Each pixel PX of the display apparatus 1 is a minimum unit for displaying an image, and the display apparatus 1 may display a desired image through a combination of the plurality of pixels PX. For example, each pixel PX may emit light of a certain color, and the display apparatus 1 may display a desired image by using light emitted from the pixels PX. For example, each pixel PX may emit red light, green light, or blue light. Each pixel PX may include a light-emitting device such as an organic light-emitting diode. The pixel PX may be connected to a pixel circuit including a thin-film transistor (TFT) and a storage capacitor.

The display area DA may have any of polygonal shapes including a quadrangular shape as shown in FIG. 1. For example, the display area DA may have a rectangular shape in which a horizontal length is greater than a vertical length, a rectangular shape in which a horizontal length is less than a vertical length, or a square shape. According to some embodiments, the display area DA, the peripheral area PA, and/or the display apparatus 1 may have one or more rounded corners. Alternatively, the display area DA may have any of various shapes such as an elliptical shape or a circular shape.

The peripheral area PA may be a non-display area where no pixels PX are located. A driver or the like for applying an electrical signal or power to the pixels PX may be located in the peripheral area PA. Pads to which various electronic devices or printed circuit boards may be electrically connected may be located in the peripheral area PA. The pads may be located in the peripheral area PA to be spaced apart from each other and may each be electrically connected to a printed circuit board or an integrated circuit device.

One or more embodiments of the present disclosure provide an electronic device including the display apparatus as described in one or more embodiments.

In ore or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

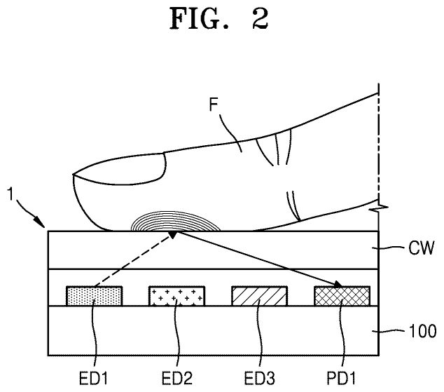

FIG. 2 is a schematic cross-sectional view illustrating a display apparatus, according to some embodiments.

Referring to FIG. 2, the display apparatus 1 according to some embodiments may further include an optical sensor as well as the plurality of pixels PX (see FIG. 1). Each of the plurality of pixels PX (see FIG. 1) may include at least one of a first light-emitting device ED1, a second light-emitting device ED2, or a third light-emitting device ED3, and the optical sensor may include a first light-receiving device PD1. The first light-emitting device ED1, the second light-emitting device ED2, and the third light-emitting device ED3 may emit light of different colors. For example, the first light-emitting device ED1 may emit green light, the second light-emitting device ED2 may emit red light, and the third light-emitting device ED3 may emit blue light.

As shown in FIG. 2, the display apparatus 1 may have a function of sensing an object, for example, a fingerprint of a finger F, contacting a cover window CW. As at least part of light reflected from the fingerprint of the user from among light emitted from at least one of the first light-emitting device ED1, the second light-emitting device ED2, or the third light-emitting device ED3 is re-incident on the first light-receiving device PD1, the first light-receiving device PD1 may detect the reflected light. For example, as green light emitted from the first light-emitting device ED1 is reflected by an object contacting the cover window CW and is re-incident on the first light-receiving device PD1, the first light-receiving device PD1 may detect the re-incident green light.

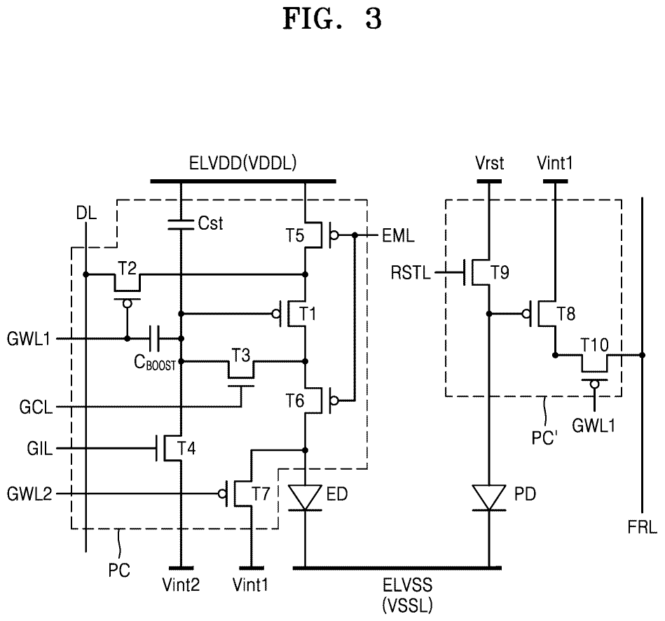

FIG. 3 is an equivalent circuit diagram illustrating a pixel circuit electrically connected to a light-emitting device and a sensor circuit electrically connected to a light-receiving device of a display apparatus, according to some embodiments.

Referring to FIG. 3, the pixel PX (see FIG. 1) may include a light-emitting device ED and a pixel circuit PC for controlling the amount of light emitted by the light-emitting device ED, and an optical sensor may include a light-receiving device PD, and a sensor circuit PC′ for controlling the amount of light received by the light-receiving device PD.

Each pixel circuit PC may be connected to a scan start line GIL, a scan control line GCL, a first scan write line GWL1, a second scan write line GWL2, an emission line EML, and a data line DL. Also, each pixel circuit PC may be connected to a first driving voltage line VDDL to which a first driving voltage ELVDD is applied, a second driving voltage line VSSL to which a second driving voltage ELVSS is applied, a first initialization voltage line to which a first initialization voltage Vint1 is applied, and a second initialization voltage line to which a second initialization voltage Vint2 is applied.

Each sensor circuit PC′ may be connected to the first scan write line GWL1, a reset line RSTL, and a fingerprint detection line FRL. Also, each sensor circuit PC′ may be connected to the second driving voltage line VSSL to which the second driving voltage ELVSS is applied, a reset voltage line to which a reset voltage Vrst is applied, and the first initialization voltage line to which the first initialization voltage Vint1 is applied.

Each pixel circuit PC may include a plurality of transistors and at least one capacitor and may be connected to the light-emitting device ED. The plurality of transistors may include first to seventh transistors T1, T2, T3, T4, T5, T6, and T7. From among the plurality of transistors, the first transistor T1 may be a driving transistor and each of the second to seventh transistors T7 may be a transistor that functions as a switch device that is turned on or turned off according to a scan signal applied to a gate electrode thereof.

The first transistor T1 may include a gate electrode, a first electrode, and a second electrode. The gate electrode of the first transistor T1 may be connected to a first electrode of the third transistor T3 and one electrode of the storage capacitor Cst, the first electrode may be connected to a second electrode of the second transistor T2 and a second electrode of the fifth transistor T5, and the second electrode may be connected to a second electrode of the third transistor T3 and a first electrode of the sixth transistor T6.

The light-emitting device ED emits light according to driving current. The amount of light emitted by the light-emitting device ED may be proportional to the driving current. The light-emitting device ED may be an organic light-emitting diode including a pixel electrode, a counter electrode, and an organic emission layer located between the pixel electrode and the counter electrode. Alternatively, the light-emitting device ED may be an inorganic light-emitting diode including an inorganic emission layer located between a pixel electrode and a counter electrode, or a quantum dot light-emitting diode including a quantum dot emission layer located between a pixel electrode and a counter electrode. Also, the light-emitting device ED may be a micro light-emitting diode. The pixel electrode of the light-emitting device ED may be connected to a second electrode of the sixth transistor T6 and a second electrode of the seventh transistor T7, and the counter electrode may be connected to the second driving voltage line VSSL.

The second transistor T2 may be turned on by a scan signal of the first scan write line GWL1 to connect the first electrode of the first transistor T1 to the data line DL. A gate electrode of the second transistor T2 may be connected to the first scan write line GWL1, a first electrode may be connected to the data line DL, and the second electrode may be connected to the first electrode of the first transistor T1.

The third transistor T3 may be turned on by a scan signal of the scan control line GCL to connect the gate electrode and the second electrode of the first transistor T1. That is, because, when the third transistor T3 is turned on, the gate electrode and the second electrode of the first transistor T1 are connected, the first transistor T1 may be driven as a diode. A gate electrode of the third transistor T3 may be connected to the scan control line GCL, the first electrode may be connected to the second electrode of the first transistor T1, and the second electrode may be connected to the gate electrode of the first transistor T1.

The fourth transistor T4 may be turned on by a scan signal of the scan start line GIL to connect the gate electrode of the first transistor T1 to the second initialization voltage line. In this case, the gate electrode of the first transistor T1 may be discharged to the second initialization voltage Vint2 of the second initialization voltage line. A gate electrode of the fourth transistor T4 may be connected to the scan start line GIL, a first electrode may be connected to the second initialization voltage line, and a second electrode may be connected to the gate electrode of the first transistor T1.

The fifth transistor T5 may be turned on by an emission signal of the emission line EML to connect the first electrode of the first transistor T1 to the first driving voltage line VDDL. A gate electrode of the fifth transistor T5 may be connected to the emission line EML, a first electrode may be connected to the first driving voltage line VDDL, and the second electrode may be connected to the first electrode of the first transistor T1.

The sixth transistor T6 may be turned on by an emission signal of the emission line EML to connect the second electrode of the first transistor T1 to the pixel electrode of the light-emitting device ED. A gate electrode of the sixth transistor T6 may be connected to the emission line EML, the first electrode may be connected to the second electrode of the first transistor T1, and a second electrode may be connected to the pixel electrode of the light-emitting device ED. When both the fifth transistor T5 and the sixth transistor T6 are turned on, the driving current may be supplied to the light-emitting device ED.

The seventh transistor T7 may be turned on by a scan signal of the second scan write line GWL2 to connect the first initialization voltage line to the pixel electrode of the light-emitting device ED. In this case, the pixel electrode of the light-emitting device ED may be discharged to the first initialization voltage Vint1. A gate electrode of the seventh transistor T7 may be connected to the second scan write line GWL2, a first electrode may be connected to the first initialization voltage line, and the second electrode may be connected to the pixel electrode of the light-emitting device ED.

The storage capacitor Cst may be formed between the gate electrode of the first transistor T1 and the first driving voltage line VDDL. One electrode of the storage capacitor Cst may be connected to the gate electrode of the first transistor T1 and the other electrode may be connected to the first driving voltage line VDDL. Accordingly, the storage capacitor Cst may maintain a potential difference between the gate electrode of the first transistor T1 and the first driving voltage line VDDL.

A boost capacitor C_{BOOST} may be formed between the gate electrode of the second transistor T2 and the gate electrode of the first transistor T1. One electrode of the boost capacitor C_{BOOST} may be connected to the first scan write line GWL1 connected to the gate electrode of the second transistor T2, and the other electrode may be connected to the gate electrode of the first transistor T1 and one electrode of the storage capacitor Cst. The boost capacitor C_{BOOST} is a boosting capacitor, and may relatively reduce a voltage for displaying black (black voltage) by increasing a voltage of a node when a signal of the first scan write line GWL1 is a voltage for turning off the second transistor T2.

Each sensor circuit PC′ may include a plurality of transistors and may be connected to the light-receiving device PD. The plurality of transistors may include eighth to tenth transistors T8, T9, and T10. From among the plurality of transistors, the eight transistor T8 may be a driving transistor, and the ninth transistor T9 and the tenth transistor T10 may be transistors that function as switch devices that are turned on or turned off according to a reset signal and a scan signal applied to gate electrodes thereof.

When a plurality of light-emitting devices ED and a plurality of light-receiving devices PD are arranged in one display apparatus 1 (see FIG. 1), a voltage wiring or a signal wiring for driving the light-emitting devices ED may be shared when driving the light-receiving devices PD. That is, because an additional arrangement of voltage wirings or signal wirings for driving the plurality of light-receiving devices PD for driving the plurality of light-receiving devices PD in the display apparatus 1 (see FIG. 1) is minimized, a resolution of the display apparatus 1 (see FIG. 1) may be ensured and the peripheral area PA (see FIG. 1) may be minimized. For example, a signal wiring connected to the gate electrode of the second transistor T2 of the pixel PX (see FIG. 1) may be shared with a signal wiring connected to the gate electrode of the tenth transistor T10 of the optical sensor. That is, the gate electrode of the second transistor T2 and a gate electrode of the tenth transistor T10 may be connected to the first scan write line GWL1. In another example, the second driving voltage line VSSL may be a common voltage wiring connected to the counter electrode of the light-emitting device ED and a counter electrode of the light-receiving device FD. In another example, the first initialization voltage line for applying the first initialization voltage Vint1 may be a common voltage wiring connected to a second electrode of the eight transistor T8 and the second electrode of the seventh transistor T7 of the optical sensor.

Each of the light-receiving devices PD may be a light-receiving diode including a sensing electrode, a counter electrode, and a photoelectric conversion layer located between the sensing electrode and the counter electrode. Each light-receiving device PD may convert light incident from the outside into an electrical signal. The light-receiving device PD may be a light-receiving diode or a phototransistor formed of a pn-type or a pin-type inorganic material. Alternatively, the light-receiving device PD may be an organic light-receiving diode including an electron donating material for generating donor ions and an electron accepting material for generating acceptor ions.

When the light-receiving device PD is exposed to external light, photocharges may be generated, and the generated photocharges may be accumulated on the sensing electrode of the light-receiving device PD. In this case, a voltage of a node electrically connected to the sensing electrode may increase. When the light-receiving device PD and the fingerprint detection line FRL are connected according to turning-on of the eighth transistor T8 and the tenth transistor T10, current may flow through the fingerprint detection line FRL in proportion to the voltage of the node where the charges are accumulated.

The eighth transistor T8 may be turned on by a voltage applied to a gate electrode to connect the first initialization voltage line to a first electrode of the tenth transistor T10. In this case, a second electrode of the tenth transistor T10 may be discharged to the first initialization voltage Vint1. The gate electrode of the eight transistor T8 may be connected to a node between the ninth transistor T9 and the light-receiving device PD, a first electrode may be connected to the first initialization voltage line, and the second electrode may be connected to the first electrode of the tenth transistor T10. The eighth transistor T8 may be a source follower amplifier that generates source-drain current in proportion to the amount of charges of the node input to the gate electrode. The first electrode of the eighth transistor T8 may be connected to the first driving voltage line VDDL or the second initialization voltage line.

The tenth transistor T10 may be turned on by a scan signal of the first scan write line GWL1 to connect the second electrode of the eighth transistor T8 to the fingerprint detection line FRL. The fingerprint detection line FRL may transmit a fingerprint detection signal to a read-out circuit. The gate electrode of the tenth transistor T10 may be connected to the first scan write line GWL1, the first electrode may be connected to the second electrode of the eighth transistor T8, and the second electrode may be connected to the fingerprint detection line FRL.

The ninth transistor T9 may be turned on by a reset signal of the reset line RSTL to reset the node connected to the gate electrode of the eighth transistor T8 to the reset voltage Vrst. A gate electrode of the ninth transistor T9 may be connected to the reset line RSTL, a first electrode may be connected to the reset voltage line, and a second electrode may be connected to the node that connects the light-receiving device PD to the eighth transistor T8. When a reset driver for outputting a reset signal of the reset line RSTL is omitted, the ninth transistor T9 may be turned on by a scan signal.

When the first electrode of each of the first to then transistors T1, T2, T3, T4, T5, T6, T7, T8, T9, and T10 is a source electrode, the second electrode may be a drain electrode. Alternatively, when the first electrode of each of the first to tenth transistors T1, T2, T3, T4, T5, T6, T7, T8, T9, and T10 is a drain electrode, the second electrode may be a source electrode.

An active layer of each of the first to tenth transistors T1, T2, T3, T4, T5, T6, T7, T8, T9, and T10 may be formed of any one of polysilicon, amorphous silicon, and an oxide semiconductor. For example, the first and second transistors T1 and T2, the fifth to eighth transistors T5, T6, T7, and T8, and the tenth transistor T10 may be P-type transistors. In this case, the active layer of each of the first and second transistors T1 and T2, the fifth to eighth transistors T5, T6, T7, and T8, and the tenth transistor T10 may be formed of polysilicon. Also, each of the third transistor T3, the fourth transistor T4, and the ninth transistor T9 may be an N-type transistor that forms an active layer formed of an oxide semiconductor.

However, embodiments are not limited thereto, and each of the first to tenth transistors T1, T2, T3, T4, T5, T6, T7, T8, T9, and T10 may be a P-type transistor. In another example, the eighth to tenth transistors T8, T9, and T10 may be formed as P-type transistors.

Although FIG. 3 illustrates various components, and connections between the components, embodiments according to the present disclosure are not limited thereto, and some embodiments may include additional components or fewer components without departing from the spirit and scope of embodiments according to the present disclosure.

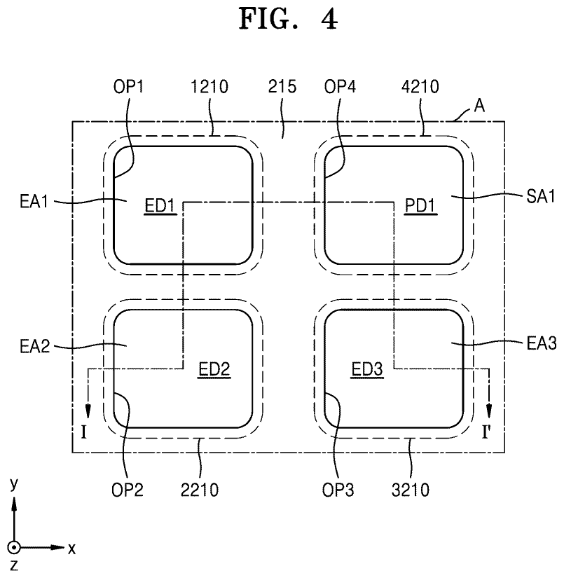

FIG. 4 is a plan view schematically illustrating a part of a display apparatus, according to some embodiments. For example, FIG. 4 is an enlarged plan view schematically illustrating a portion A of FIG. 1. FIG. 4 is a plan view on a bank layer 215 for convenience.

Referring to FIG. 4, the display apparatus 1 may include a plurality of light-emitting devices and a plurality of light-receiving devices. The plurality of light-emitting devices may include a first light-emitting device ED1, a second light-emitting device ED2, and a third light-emitting device ED3, and the plurality of light-receiving devices may include a first light-receiving device PD1. The first light-emitting device ED1, the second light-emitting device ED2, and the third light-emitting device ED3 may emit light of different colors. For example, the first light-emitting device ED1 may emit green light, the second light-emitting device ED2 may emit red light, and the third light-emitting device ED3 may emit blue light. Red light may be light belonging to a wavelength band of 580 nm to 780 nm, blue light may be light belonging to a wavelength band of 380 nm to 495 nm, and green light may be light belonging to a wavelength band of 495 nm to 580 nm. The first light-receiving device PD1 may sense an object by detecting light emitted from the first light-emitting device ED1, the second light-emitting device ED2, and/or the third light-emitting device ED3 and reflected by the object.

Each light-emitting device may include a pixel electrode, a counter electrode, and an intermediate layer located between the pixel electrode and the counter electrode, and each light-receiving device may include a sensing electrode, a counter electrode, and an intermediate layer located between the sensing electrode and the counter electrode. Accordingly, the first light-emitting device ED1 may include a first pixel electrode 1210, the second light-emitting device ED2 may include a second pixel electrode 2210, the third light-emitting device ED3 may include a third pixel electrode 3210, and the first light-receiving device PD1 may include a first sensing electrode 4210. The first pixel electrode 1210, the second pixel electrode 2210, the third pixel electrode 3210, and the first sensing electrode 4210 may be spaced apart from each other on the substrate 100 (see FIG. 5). In the specification, “on a plane” means a plane viewed in a direction perpendicular to the substrate 100. That is, “A and B spaced apart from each other on a plane” means “A and B spaced apart from each other when viewed in a direction perpendicular to the substrate 100.”

The bank layer 215 may be located on the first pixel electrode 1210, the second pixel electrode 2210, the third pixel electrode 3210, and the first sensing electrode 4210, and may cover an edge of each of the first pixel electrode 1210, the second pixel electrode 2210, the third pixel electrode 3210, and the first sensing electrode 4210. That is, the bank layer 215 may include a first opening OP1 through which a central portion of the first pixel electrode 1210 is exposed, a second opening OP2 through which a central portion of the second pixel electrode 2210 is exposed, a third opening OP3 through which a central portion of the third pixel electrode 3210 is exposed, and a fourth opening OP4 through which a central portion of the first sensing electrode 4210 is exposed.

According to some embodiments, emission layers for emitting light may be respectively located in the first opening OP1, the second opening OP2, and the third opening OP3 of the bank layer 215, and active layers for detecting light may each be located in the fourth opening OP4 of the bank layer 215. The counter electrode may be located on the emission layers and the active layers. As described above, a stacked structure of a pixel electrode, an emission layer, and a counter electrode may constitute one light-emitting device. Also, as described above, a stacked structure of a sensing electrode, an active layer, and a counter electrode may constitute one light-receiving device. One opening of the bank layer 215 may correspond to one light-emitting device and may define one emission area. Alternatively, one opening of the bank layer 215 may correspond to one light-receiving device and may define one sensing area.

For example, an emission layer for emitting green light may be located in the first opening OP1 so that the first opening OP1 defines a first emission area EA1. Likewise, an emission layer for emitting red light may be located in the second opening OP2 so that the second opening OP2 defines a second emission area EA2. An emission layer for emitting blue light may be located in the third opening OP3 so that the third opening OP3 defines a third emission area EA3. An active layer for detecting light may be located in the fourth opening OP4 so that the fourth opening OP4 defines a first sensing area SA1.

Accordingly, the size of the area of the first opening OP1 is the same as the size of the area of the first emission area EA1. The size of the area of the second opening OP2 is the same as the size of the area of the second emission area EA2, and the size of the area of the third opening OP3 is the same as the size of the area of the third emission area EA3. The size of the area of the fourth opening OP4 is the same as the size of the area of the first sensing area SA1.

Each of the first opening OP1, the second opening OP2, the third opening OP3, and the fourth opening OP4 may have a polygonal shape when viewed in a direction (z-axis direction) perpendicular to the substrate 100 (see FIG. 5). In other words, each of the first emission area EA1, the second emission area EA2, the third emission area EA3, and the first sensing area SA1 may have a polygonal shape when viewed in the direction (z-axis direction) perpendicular to the substrate 100. In FIG. 4, each of the first emission area EA1, the second emission area EA2, the third emission area EA3, and the first sensing area SA1 has a quadrangular shape, specifically, a quadrangular shape with rounded corners, when viewed in the direction (z-axis direction) perpendicular to the substrate 100. However, embodiments according to the present disclosure are not limited thereto. For example, each of the first emission area EA1, the second emission area EA2, the third emission area EA3, and the first sensing area SA1 may have a circular shape or an elliptical shape when viewed in the direction (z-axis direction) perpendicular to the substrate 100.

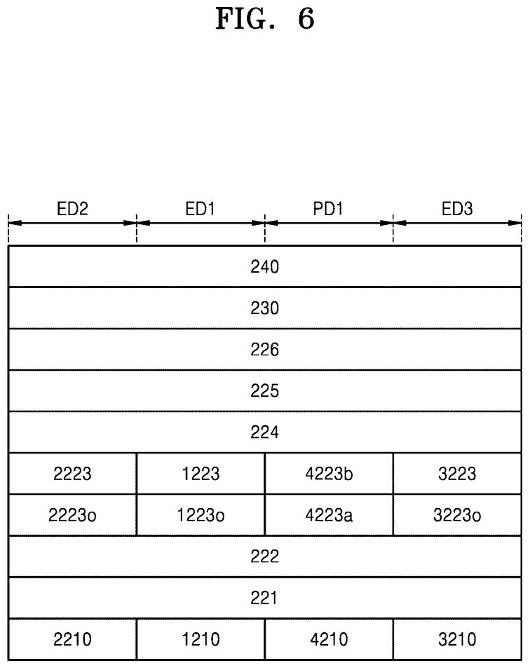

FIG. 5 is a cross-sectional view schematically illustrating a part of a display apparatus, according to some embodiments. For example, FIG. 5 is a schematic cross-sectional view taken along the line I-I′ of the display apparatus of FIG. 4. FIG. 6 is a conceptual view schematically illustrating a portion of a display apparatus, according to some embodiments. For example, FIG. 6 is a cross-sectional view schematically illustrating a light-emitting device and a light-receiving device of a display apparatus, according to some embodiments.

As shown in FIG. 5, the display apparatus 1 according to the present embodiments may include the substrate 100. The substrate 100 may include any of various flexible or bendable materials. For example, the substrate 100 may include glass, a metal, or a polymer resin. Also, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. However, various modifications may be made. For example, the substrate 100 may have a multi-layer structure including two layers each including a polymer resin and a barrier layer including an inorganic material (e.g., silicon oxide, silicon nitride, or silicon oxynitride) and located between the two layers.

The first to third light-emitting devices ED1, ED2, and ED3, the first light-receiving device PD1, the pixel circuit PC, and the sensor circuit PC′ may be located on the substrate 100. The pixel circuit PC may be electrically connected to each of the first to third light-emitting devices ED1, ED2, and ED3, and the sensor circuit PC′ may be electrically connected to the first light-receiving device PD1.

Light emission may be controlled when each of the first light-emitting device ED1, the second light-emitting device ED2, and the third light-emitting device ED3 is connected to the pixel circuit PC. Also, light direction may be controlled when the first light-receiving device PD1 is electrically connected to the sensor circuit PC′. The pixel circuit PC may include a plurality of thin-film transistors TFT and a storage capacitor Cst, and may have substantially the same structure as that of the pixel circuit PC described with reference to FIG. 3. One thin-film transistor TFT is illustrated in FIG. 5 for convenience of illustration, and the thin-film transistor TFT may correspond to the first transistor T1 (see FIG. 3) described above. Likewise, the sensor circuit PC′ may include a plurality of thin-film transistors TFT′, and may have substantially the same structure as that of the sensor circuit PC′ described with reference to FIG. 3. One thin-film transistor TFT′ is illustrated in FIG. 5 for convenience of illustration, and the thin-film transistor TFT′ may correspond to the eighth transistor T8 (see FIG. 3) described above. For convenience of explanation, one pixel circuit PC will be mainly described.

A buffer layer 201 including an inorganic material such as silicon oxide, silicon nitride, and/or silicon oxynitride may be located between the thin-film transistor TFT and the substrate 100. The buffer layer 201 may increase smoothness of a top surface of the substrate 100, or may prevent, reduce, or minimize penetration of impurities from the substrate 100 into a semiconductor layer Act of the thin-film transistor TFT.

As shown in FIG. 5, the thin-film transistor TFT may include the semiconductor layer Act including amorphous silicon, polysilicon, an organic semiconductor material, or an oxide semiconductor material. The thin-film transistor TFT may include a gate electrode GE, a source electrode SE, and/or a drain electrode DE. The first gate electrode GE may include any of various conductive materials and may have any of various layer structures. For example, the first gate electrode GE may include a molybdenum (Mo) layer and an aluminum (Al) layer. Alternatively, the gate electrode GE may include a TiNx layer, an Al layer, and/or a titanium (Ti) layer. Each of the source electrode SE and the drain electrode DE may also include any of various conductive materials and may have any of various layer structures. For example, each of the source electrode SE and the drain electrode DE may include a Ti layer, an Al layer, and/or a copper (Cu) layer.

In order to ensure insulation between the semiconductor layer Act and the gate electrode GE, a gate insulating layer 203 including an inorganic material such as silicon oxide, silicon nitride, and/or silicon oxynitride may be located between the semiconductor layer Act and the gate electrode GE. Although the gate insulating layer 203 has a shape corresponding to an entire surface of the substrate 100 and includes contact holes formed in pre-set portions in FIG. 5, the disclosure is not limited thereto. For example, the gate insulating layer 203 may be patterned into the same shape as the gate electrode GE.

A first interlayer insulating layer 205 including an inorganic material such as silicon oxide, silicon nitride, and/or silicon oxynitride may be located on the gate electrode GE. The first interlayer insulating layer 205 may have a single or multi-layer structure including the above material. Such an insulating film including an inorganic material may be formed by using chemical vapor deposition (CVD) or atomic layer deposition (ALD).

The storage capacitor Cst may include a first electrode CE1 and a second electrode CE2 overlapping each other with the first interlayer insulating layer 205 therebetween. The storage capacitor Cst may overlap the thin-film transistor TFT. In this regard, although the gate electrode GE of the thin-film transistor TFT is the first electrode CE1 of the storage capacitor Cst in FIG. 5, the disclosure is not limited thereto. For example, the storage capacitor Cst may not overlap the thin-film transistor TFT. The second gate electrode CE2 of the storage capacitor Cst may include a conductive material including molybdenum (Mo), aluminum (Al), copper (Cu), or titanium (Ti) and may have a single or multi-layer structure including the above material.

A second interlayer insulating layer 207 including an inorganic material such as silicon oxide, silicon nitride, and/or silicon oxynitride may be located on the second electrode CE2 of the storage capacitor Cst. The second interlayer insulating layer 207 may have a single or multi-layer structure including the above material.

The source electrode SE and the drain electrode DE may be located on the second interlayer insulating layer 207. Each of the source electrode SE and the drain electrode DE may include a material having excellent conductivity. Each of the source electrode SE and the drain electrode DE may include a conductive material including molybdenum (Mo), aluminum (AI), copper (Cu), or titanium (Ti) and may have a single or multi-layer structure including the above material. For example, each of the source electrode SE and the drain electrode DE may have a multi-layer structure including Ti/Al/Ti. The disclosure is not limited thereto. For example, the thin-film transistor TFT may include only one of the source electrode SE and the drain electrode DE or may not include both the source electrode SE and the drain electrode DE.

A planarization layer 208 may be located to cover the thin-film transistor TFT and the storage capacitor Cst. The planarization layer 208 may include an organic insulating material. For example, the planarization layer 208 may include photoresist, benzocyclobutene (BCB), polyimide, hexamethyldisiloxane (HMDSO), polymethylmethacrylate (PMMA), polystyrene, a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof. According to some embodiments, a third interlayer insulating layer may be further located under the planarization layer 208. The third interlayer insulating layer may include an inorganic insulating material such as silicon oxide, silicon nitride, or silicon oxynitride.

The first light-emitting device ED1, the second light-emitting device ED2, the third light-emitting device ED3, and the first light-receiving device PD1 may be located on the planarization layer 208 to be spaced apart from each other. The first light-emitting device ED1, the second light-emitting device ED2, and the third light-emitting device ED3 may emit light of different colors. For example, the first light-emitting device ED1 may emit green light, the second light-emitting device ED2 may emit red light, and the third light-emitting device ED3 may emit blue light. The first light-receiving device PD1 may detect light emitted from the first to third light-emitting devices ED1, ED2, and ED3 and reflected by an object.

The first light-emitting device ED1 may include a first pixel electrode 1210, a first intermediate layer 1220, and a counter electrode 230. The second light-emitting device ED2 may include a second pixel electrode 2210, a second intermediate layer 2220, and the counter electrode 230. The third light-emitting device ED3 may include a third pixel electrode 3210, a third intermediate layer 3220, and the counter electrode 230. The first light-receiving device PD1 may include a first sensing electrode 4210, a fourth intermediate layer 4220, and the counter electrode 230. That is, the first pixel electrode 1210, the second pixel electrode 2210, the third pixel electrode 3210, and the first sensing electrode 4210 respectively provided in the first light-emitting device ED1, the second light-emitting device ED2, the third light-emitting device ED3, and the first light-receiving device PD1 may be patterned and provided for respective pixels. The counter electrode 230 of the first light-emitting device ED1, the second light-emitting device ED2, the third light-emitting device ED3, and the first light-receiving device PD1 may be integrally provided over the first light-emitting device ED1, the second light-emitting device ED2, the third light-emitting device ED3, and the first light-receiving device PD1. The first intermediate layer 1220, the second intermediate layer 2220, the third intermediate layer 3220, and the fourth intermediate layer 4220 may be respectively located between the first pixel electrode 1210, the second pixel electrode 2210, the third pixel electrode 3210, and the first sensing electrode 4210 and the counter electrode 230.

The first pixel electrode 1210, the second pixel electrode 2210, the third pixel electrode 3210, and the first sensing electrode 4210 may be located on the substrate 100 to be spaced apart from each other. The first pixel electrode 1210, the second pixel electrode 2210, the third pixel electrode 3210, and the first sensing electrode 4210 may be reflective electrodes. For example, each of the first pixel electrode 1210, the second pixel electrode 2210, the third pixel electrode 3210, and the first sensing electrode 4210 includes a light-transmitting conductive layer formed of a light-transmitting conductive oxide such as ITO, In₂O₃, or IZO and a reflective layer formed of a metal such as Al or Ag. For example, each of the first pixel electrode 1210, the second pixel electrode 2210, the third pixel electrode 3210, and the first sensing electrode 4210 may have a three-layer structure including ITO/Ag/ITO.

Each of the first pixel electrode 1210, the second pixel electrode 2210, and the third pixel electrode 3210 may contact any one of the source electrode SE and the drain electrode DE as shown in FIG. 5 to be electrically connected to the thin-film transistor TFT. For example, each of the first pixel electrode 1210, the second pixel electrode 2210, and the third pixel electrode 3210 may contact any one of the source electrode SE and the drain electrode DE through a contact hole formed in the planarization layer 208. Likewise, the first sensing electrode 4210 may be electrically connected to the thin-film transistor TFT′ through a contact hole formed in the planarization layer 208.

The bank layer 215 may be located on the planarization layer 208. The bank layer 215 may have an opening corresponding to each of the first to third light-emitting devices ED1, ED2, and ED3 and the first light-receiving device PD1, that is, an opening through which a central portion of at least one pixel electrode (or sensing electrode) is exposed, to define an emission area and a sensing area. For example, the bank layer 215 may have a plurality of openings, for example, first to fourth openings OP1, OP2, OP3, and OP4 (see FIG. 4) through which central portions of the first pixel electrode 1210, the second pixel electrode 2210, the third pixel electrode 3210, and the first sensing electrode 4210 are exposed. Also, the bank layer 215 may increase a distance between a pixel electrode and the counter electrode 230 or a distance between a sensing electrode and the counter electrode 230. Accordingly, instances of an arc or the like occurring at edges of the first to third pixel electrodes 1210, 2210, and 3210 or an edge of the first sensing electrode 4210 may be prevented or reduced. The bank layer 215 may include an organic material such as polyimide or hexamethyldisiloxane (HMDSO).

The counter electrode 230 may be located on the first pixel electrode 1210. The counter electrode 230 may be integrally provided over the first light-emitting device ED1, the second light-emitting device ED2, the third light-emitting device ED3, and the first light-receiving device PD1. Accordingly, the counter electrode 230 may also be located on the second pixel electrode 2210, the third pixel electrode 3210, and the first sensing electrode 4210. The counter electrode 230 may be a transflective electrode or a transmissive electrode. For example, the counter electrode 230 may be a transmissive electrode including a transmissive conductive layer formed of ITO, In203, or IZO or a transflective electrode including a transflective film including a metal such as Al or Ag. For example, the counter electrode 230 may be a transflective film including at least one of magnesium (Mg) or Ag.

As the first to third pixel electrodes 1210, 2210, and 3210 are reflective electrodes and the counter electrode 230 is a transflective electrode, each of the first to third light-emitting devices ED1, ED2, and ED3 may have a front resonance structure. When light is repeatedly reflected between the first to third pixel electrodes 1210, 2210, and 3210, which are reflective electrodes, and the counter electrode 230, which is a transflective electrode, light having a specific wavelength may be amplified by constructive interference, light having other wavelengths may be suppressed, and the amplified light may pass through the counter electrode 2330, which is a transflective electrode, and may be emitted to the outside. That is, through the front resonance structure, the front light emission efficiency of the first to third light-emitting devices ED1, ED2, and ED3 may be relatively improved.

As the first sensing electrode 4210 is a reflective electrode and the counter electrode 230 is a transflective electrode, the first light-receiving device PD1 may also have a front resonance structure. However, the first light-receiving device PD1 may neutralize a resonance phenomenon through an active layer 4223 described below. The resonance structure of the first light-receiving device PD1 will be described below in more detail.

Referring back to FIGS. 5 and 6, an intermediate layer may be located between the first to third pixel electrodes 1210, 2210, and 3210 and the first sensing electrode 4210 and the counter electrode 230. The intermediate layer may include the first intermediate layer 1220, the second intermediate layer 2220, the third intermediate layer 3220, and the fourth intermediate layer 4220. The first intermediate layer 1220 may be located between the first pixel electrode 1210 and the counter electrode 230. The second intermediate layer 2220 may be located between the second pixel electrode 2210 and the counter electrode 230, and the third intermediate layer 3220 may be located between the third pixel electrode 3210 and the counter electrode 230. The fourth intermediate layer 4220 may be located between the first sensing electrode 4210 and the counter electrode 230.

The first intermediate layer 1220 may include a first common layer 221, a second common layer 222, a first emission layer 1223, a buffer layer 224, a third common layer 225, and a fourth common layer 226. The second intermediate layer 2220 may include the first common layer 221, the second common layer 222, a second emission layer 2223, the buffer layer 224, the third common layer 225, and the fourth common layer 226. The third intermediate layer 3220 may include the first common layer 221, the second common layer 222, a third emission layer 3223, the buffer layer 224, the third common layer 225, and the fourth common layer 226. The fourth intermediate layer 4220 may include the first common layer 221, the second common layer 222, a first active layer 4223, the buffer layer 224, the third common layer 225, and the fourth common layer 226.

In this case, the first common layer 221, the second common layer 222, the buffer layer 224, the third common layer 225, and the fourth common layer 226 may be integrally provided over the first to third light-emitting devices ED1, ED2, and ED3 and the first light-receiving device PD1. That is, the first common layer 221, the second common layer 222, the buffer layer 224, the third common layer 225, and the fourth common layer 226 may be formed over the entire surface of the substrate 100. An emission layer 223 and the first active layer 4223 may be patterned and individually provided for each light-emitting device and light-receiving device.

According to some embodiments, the first light-emitting device ED1 may emit red light, the second light-emitting device ED2 may emit green light, and the third light-emitting device ED3 may emit blue light. To implement such light emission, the first emission layer 1223 may emit green light, the second emission layer 2223 may emit red light, and the third emission layer 3223 may emit blue light. The first light-receiving device PD1 may detect light emitted from the first to third light-emitting devices ED1, ED2, and ED3 and reflected by an object. To implement such light detection, the first active layer 4223 may have a wide detectable light wavelength range and may absorb light in a visible band and light in a near-infrared band. This is due to a resonance neuralization phenomenon of the light-receiving device PD, and a non-resonance structure of the light-receiving device PD will be described below.

The first to third emission layers 1223, 2223, and 3223 may include an organic material including a fluorescent or phosphorescent material that emits red, green, blue, or white light. The first to third emission layers 1223, 2223, and 3223 may be organic emission layers including a low molecular weight organic material or a high molecular weight organic material. For example, the first to third emission layers 1223, 2223, and 3223 are organic emission layers and may include copper phthalocyanine, tris-8-hydroxyquinoline aluminum, a poly-phenylenevinylene (PPV)-based material, or a polyfluorene-based material.

According to some embodiments, the first to third emission layers 1223, 2223, and 3223 may include a host material and a dopant material. The dopant material is a material for emitting light of a specific color and may include a light-emitting material. The light-emitting material may include at least one of a phosphorescent dopant, a fluorescent dopant, or quantum dots. The host material is a main material of the first to third emission layers 1223, 2223, and 3223 and helps the dopant material to emit light.

The first active layer 4223 may receive light from the outside to generate excitons and then may separate the generated excitons into holes and electrons. When a (+) potential is applied to the first sensing electrode 4210 and a (−) potential is applied to the counter electrode 230, the holes separated in the first active layer 4223 may move toward the counter electrode 230 and the electrons separated in the first active layer 4223 may move toward the first sensing electrode 4210. Accordingly, photocurrent may be formed in a direction from the first sensing electrode 4210 to the counter electrode 230. When a bias is applied between the first sensing electrode 4210 and the counter electrode 230, dark current may flow through the first light-receiving device PD1. The first light-receiving device PD1 may detect the amount of light from a ratio of photocurrent to dark current.

The first active layer 4223 may include a p-type organic semiconductor and an n-type organic semiconductor. According to some embodiments, the first active layer 4223 may include a first layer 4223a including an electron donor material and a second layer 4223b including an electron acceptor material. That is, the first active layer 4223 may have a double-layer structure in which the first layer 4223a and the second layer 4223b located on the first layer 4223a are stacked. In this case, the first layer 4223a may include a p-type organic semiconductor, and the second layer 4223b may include an n-type organic semiconductor. The p-type organic semiconductor may function as an electron donor, and the n-type organic semiconductor may function as an electron acceptor. The first layer 4223a including the p-type organic semiconductor and the second layer 4223b including the n-type organic semiconductor may form a PN junction. Excitons may be efficiently separated into holes and charges due to photoinduced charge separation occurring at an interface between these layers.

The p-type organic semiconductor included in the first layer 4223a may be a compound functioning as an electron donor for supplying electrons. According to some embodiments, the first layer 4223a may include at least one of boron subphthalocyanine chloride (SubPc), or boron sub-2,3-naphthalocyanine chloride (SubNc). When the first layer 4223a includes SubPc or SubNc, light in a wider wavelength band may be absorbed. However, the p-type organic semiconductor is not limited thereto, and the p-type organic semiconductor may be an organic compound capable of donating electrons. Examples of the p-type organic semiconductor include, but are not limited to, a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a naphthalocyanine compound, a cyanine compound, a merocyanine compound, an oxonol compound, a polyamine compound, an indole compound, a pyrrole compound, a pyrazole compound, a polyarylene compound, a condensed aromatic carbocyclic compound (a naphthalene derivative, an anthracene derivative, a phenanthrene derivative, a tetracene derivative, a pyrene derivative, a perylene derivative, or a fluoranthene derivative), and a metal complex having a nitrogen-containing heterocyclic compound as a ligand.

The n-type organic semiconductor included in the second layer 4223b may be a compound functioning as an electron acceptor for accepting electrons. According to some embodiments, the second layer 4223b may include at least one of perylenetetracarboxylic dianhydride (PTCDA), 1,4,5,8-naphthalenetetracarboxylic dianhydride (NTCDA), 3,4,9,10-perylenetetracarboxylic diimide (PTCDI), naphthalenetetracarboxylic diimide (NTCDI), C60 fullerene, or C70 fullerene. However, the n-type organic semiconductor is not limited thereto, and the n-type organic semiconductor may be an organic compound capable of accepting electrons. Examples of the n-type organic semiconductor may include, but are not limited to, fullerene, a fullerene derivative, a condensed aromatic carbocyclic compound (a naphthalene derivative, an anthracene derivative, a phenanthrene derivative, a tetracene derivative, a pyrene derivative, a perylene derivative, or a fluoranthene derivative), a 5- to 7-membered heterocyclic compound containing a nitrogen atom, an oxygen atom, or a sulfur atom (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrrolidine, pyrrolopyridine, thiadiazolopyridine, dibenzazepine, or tribenzazepine), a polyarylene compound, a fluorene compound, a cyclopentadiene compound, a silyl compound, and a metal complex having a nitrogen-containing heterocyclic compound as a ligand.

Each of the first to third light-emitting devices ED1, ED2, and ED3 may further include an optical auxiliary layer 2230 to adjust an optical length for micro-cavity. The optical auxiliary layer 2230 may be located between a hole transport region described below and the emission layer 223. For example, the optical auxiliary layer 2230 may be located between the second common layer 222 and the emission layer 223. That is, a bottom surface of the emission layer 223 may directly contact a top surface of the corresponding optical auxiliary layer 2230.

The optical auxiliary layer 2230 may be patterned and provided for each light-emitting device. For example, the optical auxiliary layer 2230 may include a first optical auxiliary layer 12230 located on the first light-emitting device ED1, a second optical auxiliary layer 22230 located on the second light-emitting device ED2, and a third optical auxiliary layer 32230 located on the third light-emitting device ED3. The optical auxiliary layer 2230 may increase light emission efficiency through a front resonance structure by compensating for a resonance distance according to a wavelength of light emitted from the emission layer 223. Accordingly, the optical auxiliary layer 2230 may have a thickness proportional to a wavelength of a light emitted from a light-emitting device. For example, the second optical auxiliary layer 22230 of the second light-emitting device ED2 for emitting red light having a wavelength of 580 nm to 780 nm may have a thickness of 650 Å to 900 Å. The first optical auxiliary layer 12230 of the first light-emitting device ED1 for emitting green light having a wavelength of 495 nm to 580 nm may have a thickness of 250 Å to 500 Å. The third optical auxiliary layer 32230 of the third light-emitting device ED3 for emitting blue light having a wavelength of 380 nm to 495 nm may have a thickness of 10 Å to 100 Å.

Because the optical auxiliary layer 2230 is located between the hole transport region and the emission layer 223, the optical auxiliary layer 2230 may include a material of a hole transport layer (HTL). For example, the optical auxiliary layer 2230 may be formed of the same material as that of the second common layer 222 described below. For example, the optical auxiliary layer 2230 may include a carbazole-based derivative such as N-phenylcarbazole or polyvinylcarbazole, a fluorene-based derivative, N,N′-bis(3-methylphenyl)-N,N′-diphenyl-[1,1-biphenyl]-4,4′-diamine (TPD), a triphenylamine-based derivative such as 4,4′,4″-tris (N-carbazolyl)triphenylamine (TCTA), N,N′-di(naphthalene-I-yl)-N,N′-diplienyl-benzidine (NPB), 4,4′-cyclohexylidenebis[N,N-bis(4-methylphenyl)benzenamine] (TAPC), 4,4′-bis[N,N′-(3-tolyl)amino]-3,3′-dimethylbiphenyl (HMTPD), 9-(4-tert-butylphenyl)-3,6-bis (triphenylsilyl)-9H-carbazole (CzSi), 9-phenyl-9H-3,9′-bicarbazole (CCP), 1,3-bis(N-carbazolyl)benzene (mCP), or 1,3-bis(1,8-dimethyl-9H-carbazol-9-yl)benzene (mDCP).

In contrast, the first light-receiving device PD1 may not include the optical auxiliary layer 2230 for adjusting an optical distance. That is, the optical auxiliary layer 2230 may not be located between the first sensing electrode 4210 and the first active layer 4223, unlike the first and second light-emitting devices ED1, ED2, and ED3. In other words, a bottom surface of the first active layer 4223 may directly contact a top surface of the second common layer 222. This may be to implement a high-resolution image on the display apparatus 1.

As a comparative example, in order for the first light-receiving device PD1 to absorb green light, the optical auxiliary layer 2230 located in the first light-receiving device PD1 may be deposited simultaneously with the first optical auxiliary layer 12230 of the first light-emitting device ED1 for emitting green light. However, when it is necessary to implement a high-resolution image, it may be difficult to manufacture a mask that may simultaneously deposit the first optical auxiliary layer 12230 and the optical auxiliary layer 2230 for the first light-receiving device PD1. Also, when the first optical auxiliary layer 12230 and the optical auxiliary layer 2230 for the first light-receiving device PD1 are deposited, an additional process and device may be required, which may be disadvantageous in terms of productivity. Accordingly, in the display apparatus 1 according to some embodiments, in order to ensure productivity and implement a high-resolution image, the optical auxiliary layer 2230 may not be located in the first light-receiving device PD1.

However, when the first light-receiving device PD1 does not include the optical auxiliary layer 2230, an optical distance for front resonance of the first light-receiving device PD1 may not be adjusted. To solve this problem, the display apparatus 1 according to some embodiments may neutralize a resonance phenomenon in the first light-receiving device PD1 and may increase the light absorption efficiency of the first active layer 4223 itself, by using the first layer 4223a included in the first active layer 4223.

As described above, the first layer 4223a may include an electron donor material, that is, a p-type organic semiconductor material. The p-type organic semiconductor material included in the first layer 4223a may be a material having a high absorbance. Accordingly, when a thickness of the first layer 4223a is increased, light absorption efficiency of the first active layer 4223 itself may be relatively improved. Also, when the first layer 4223a is formed thick without locating an optical auxiliary layer in the first light-receiving device PD1, light reflected between the first sensing layer 4210 and the counter electrode 230 may be absorbed into the first layer 4223a, thereby neutralizing a resonance phenomenon. Accordingly, while an existing light-receiving device absorbs light of a single color in a narrow wavelength band by using a front resonance phenomenon, the first light-receiving device PD1 may absorb light in a wider wavelength band by using light absorption characteristics of the first layer 4223a.

As a thickness of the first layer 4223a is increased, a thickness of the first layer 4223a may be at least a thickness of the second layer 4223b in a thickness direction of the substrate 100. According to some embodiments, a thickness of the first layer 4223a may be 200 Å to 600 Å, and a thickness of the second layer 4223b may be 50 Å to 500 Å. When the first layer 4223a has a thickness of 200 Å or more, the first layer 4223a may neutralize front resonance in the first light-receiving device PD1 and may increase a wavelength band of light that may be absorbed by the first light-receiving device PD1 by using a unique spectrum of a light-absorbing material included in the first layer 4223a.

However, a thickness of the first layer 4223a may vary according to an absorbance of an electron donor material included in the first layer 4223a. A thickness of the first layer 4223a may be inversely proportional to an absorbance of the first layer 4223a. According to some embodiments, an absorbance of the first layer 4223a may be 0.2 to 0.6.

For example, a thickness of the first layer 4223a may satisfy Equation 1.

$$T = 120 / a \qquad Equation 1$$

where T is a thickness of the first layer 4223a and a may be an absorbance of a material included in the first layer 4223a. For example, when an absorbance of a material included in the first layer 4223a is 0.2, the first layer 4223a may have a thickness of at least 600 Å. Alternatively, when an absorbance of a material included in the first layer 4223a is 0.6, the first layer 4223a may have a thickness of at least 200 Å.

As a result, as the first layer 4223a is formed with a thickness equal to or greater than a minimum thickness corresponding to an absorbance of the first layer 4223a so that a resonance phenomenon of the first light-receiving device PD1 is neutralized and the first active layer 4223 may absorb light in a wider wavelength band, the light absorption efficiency and sensing sensitivity of the first light-receiving device PD1 may be relatively improved. In particular, the display apparatus 1 may read various information from a user according to a wavelength band of light absorbed by the first light-receiving device PD1. For example, when light absorbed by the first light-receiving device PD1 has a short wavelength, only information about a surface level of the user's fingerprint may be read, but when light absorbed by the first light-receiving device PD1 has a long wavelength, even information in the user's blood vessels may be read. Accordingly, because the display apparatus 1 according to an embedment may neutralize a resonance phenomenon and may absorb light in a wide wavelength band by increasing a thickness of the first layer 4223a, various information may be read from the user, thereby increasing usability.

However, a structure of the first active layer 4223 is not limited to the stacked structure as described above. In some other embodiments, the first active layer 4223 may be a mixed layer in which an electron donor material and an electron acceptor material are mixed. In this case, the first active layer 4223 may be formed by co-depositing a p-type organic semiconductor and an n-type organic semiconductor. Even when the first active layer 4223 is a mixed layer, the first active layer 4223 may have a thickness equal to or greater than a minimum thickness capable of neutralizing a resonance phenomenon.

The first to third light-emitting devices ED1, ED2, and ED3 and the first light-receiving device PD1 may further include a charge auxiliary layer that facilitates the movement of holes and electrons. The first common layer 221, the second common layer 222, the buffer layer 224, the third common layer 225, and the fourth common layer 226 may be included in the charge auxiliary layer. The first common layer 221 and the second common layer 222 may be located between the first to third pixel electrodes 1210, 2210, and 3210 and the first to third emission layers 1223, 2223, and 3223. The buffer layer 224, the third common layer 225, and the fourth common layer 226 may be located between the first to third emission layers 1223, 2223, and 3223 and the counter electrode 230 and may be located between the first active layer 4223 and the counter electrode 230. That is, the first to fourth common layers 221, 222, 225, and 226 and the buffer layer 224 may be integrally provided over the first to third light-emitting devices ED1, ED2, and ED3 and the first light-receiving device PD1.

According to some embodiments, a hole transport region may be defined between the first to third pixel electrodes 1210, 2210, and 3210 and the first to third emission layers 1223, 2223, and 3223 and between the first sensing electrode 4210 and the first active layer 4223. Also, an electron transport region may be defined between the first to third emission layers 1223, 2223, and 3223 and the counter electrode 230 and between the first active layer 4223 and the counter electrode 230.

The hole transport region may facilitate the movement of holes and may have a single or multi-layer structure. The hole transport region may include at least one of a hole injection layer (HIL), a hole transport layer, or an electron blocking layer (EBL). According to some embodiments, the first common layer 221 located in the hole transport region may be a hole injection layer (HIL), and the second common layer 222 may be a hole transport layer (HTL).

A thickness of the hole transport region may be about 50 Å to about 10000 Å, for example, about 100 Å to about 4000 Å. When the hole transport region includes a hole injection layer, a hole transport layer, or a combination thereof, a thickness of the hole injection layer (HIL) may be about 100 Å to about 9000 Å, for example, about 100 Å to about 1000 Å, and a thickness of the hole transport layer (HTL) may be about 50 Å to about 2000 Å, for example, about 100 Å to about 1500 Å. When thicknesses of the hole injection layer (HIL) and the hole transport layer (HTL) satisfy the above ranges, satisfactory hole transport characteristics may be obtained without a substantial increase in a driving voltage.

The first common layer 221 and the second common layer 222 include at least one selected from among m-MTDATA, TDATA, 2-TNATA, NPB (NPD), β-NPB, TPD, Spiro-TPD, Spiro-NPB, methylated-NPB, TAPC, HMTPD, 4,4′,4-tris (N-carbazolyl)triphenylamine (4,4′,4-tris (N-carbazolyl)triphenylamine) (TCTA), polyaniline/dodecylbenzenesulfonic acid (polyaniline/dodecylbenzenesulfonic acid) (Pani/DBSA), polyaniline/Camphor sulfonic acid) (Pani/CSA), poly(3,4-ethylenedioxythiophene)/poly(4-styrenesulfonate) (poly (3, contains at least one selected from 4-ethylenedioxythiophene)/poly(4-styrenesulfonate) (PEDOT/PSS), and polyaniline/poly(4-styrenesulfonate) (PANI/PSS).

The electron transport region facilitates the movement of electrons and may have a single or multi-layer structure. The electron transport region may include at least one of an electron injection layer (EIL), an electron transport layer (ETL), or a hole blocking layer (HBL). According to some embodiments, the third common layer 225 located in the electron transport region may be an electron transport layer (ETL) and the fourth common layer 226 may be an electron injection layer (EIL).

A thickness of the electron transport region may be about 100 Å to about 5000 Å, for example, about 160 Å to about 4000 Å. When the electron transport region includes a buffer layer, an electron transport layer, an electron injection layer, or a combination thereof, thicknesses of the buffer layer, the electron transport layer, and the electron injection layer may be independent of each other. For example, a thickness of the electron injection layer may be about 10 Å to about 1000 Å, for example, about 10 Å to about 300 Å, and a thickness of the electron transport layer may be about 100 Å to about 1000 Å, for example, about 150 Å to about 500 Å. When thicknesses of the buffer layer, the electron transport layer, the electron injection layer, and/or the electron transport region satisfy the above ranges, satisfactory electron transport characteristics may be obtained without a substantial increase in a driving voltage.

The buffer layer 224 may include an inorganic material such as silicon oxide, silicon nitride, and/or silicon oxynitride, and the third common layer 225 and the fourth common layer 226 may include at least one compound selected from among 2,9-dimethyl-4,7-diphenyl-1,10-phenanthroline (BCP), 4,7-diphenyl-1,10-phenanthroline (Bphen), Alq3, BAlq, 3-(biphenyl-4-yl)-5-(4-tert-butylphenyl)-4-phenyl-4H-1,2,4-triazole (TAZ), and NTAZ.

A capping layer 240 may be located on the first to third light-emitting devices ED1, ED2, and ED3 and the first light-receiving device PD1 having the above structure. That is, the capping layer 240 may be located on the counter electrode 230 and may be integrally formed over the entire surface of the substrate 100. The capping layer 240 may suppress penetration of impurities such as water or oxygen into the display apparatus 1, thereby relatively improving the reliability of the display apparatus 1.

The capping layer 240 may be an organic capping layer including an organic material, an inorganic capping layer including an inorganic material, or an organic-inorganic composite capping layer including an organic material and an inorganic material. The capping layer 240 may include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof.

According to some embodiments, an encapsulation portion may be located on the capping layer 240. The encapsulation portion may be located on the first to third light-emitting devices ED1, ED2, and ED32 and the first light-receiving device PD1 to protect the first to third light-receiving devices ED1, ED2, and ED3 and the first light-receiving device PD1 from moisture or oxygen. The encapsulation portion may include at least one inorganic encapsulation layer and at least one organic encapsulation layer. For example, the encapsulation portion may include an inorganic film including silicon nitride (SiNx), silicon oxide (SiOx), indium tin oxide, indium zinc oxide, or any combination thereof, and an organic film including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate or polyacrylic acid), an epoxy resin (e.g., aliphatic glycidyl ether (AGE)), or any combination thereof.

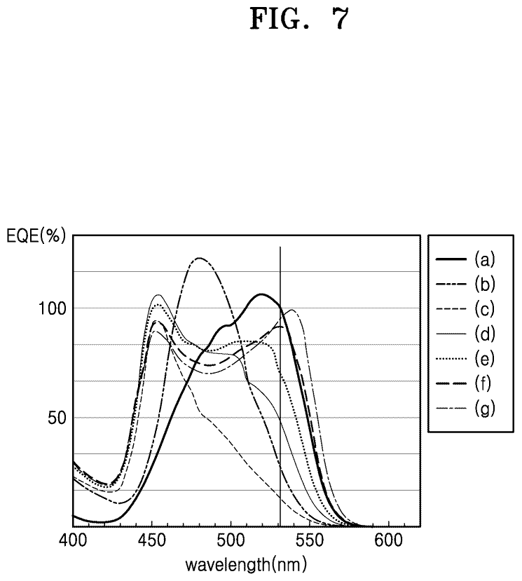

FIG. 7 is a graph illustrating external quantum efficiency according to a wavelength of a display apparatus according to a comparative example and a display apparatus according to some embodiments.

FIG. 7 is a graph illustrating a result obtained after measuring external quantum efficiency (EQE) according to a wavelength absorbed by a light-receiving device of a display apparatus and comparing comparative examples with embodiments. A horizontal axis of the graph of FIG. 7 represents a wavelength (nm) absorbed by a light-receiving device and a vertical axis represents EQE (%) of the light-receiving device. (a) to (c) of FIG. 7 show evaluation results for Comparative Example 1 to Comparative Example 3, and (c) to (g) of FIG. 7 show evaluation results for Embodiment 1 to Embodiment 4.

In a display apparatus of Comparative Example 1, a light-receiving device included an optical auxiliary layer, a first layer of an active layer had a thickness of 100 Å, and a second layer of the active layer had a thickness of 340 Å. In a display apparatus of Comparative Example 2, a light-receiving device did not include an optical auxiliary layer, a first layer of an active layer had a thickness of 100 Å, and a second layer of the active layer had a thickness of 340 Å. In a display apparatus of Comparative Example 2, a light-receiving device did not include an optical auxiliary layer, a first layer of an active layer had a thickness of 100 Å, and a second layer of the active layer had a thickness of 100 Å.

In a display apparatus of Embodiment 1, a light-receiving device did not include an optical auxiliary layer, a first layer of an active layer had a thickness of 200 Å, and a second layer of the active layer had a thickness of 100 Å. In a display apparatus of Embodiment 2, a light-receiving device did not include an optical auxiliary layer, a first layer of an active layer had a thickness of 250 Å, and a second layer of the active layer had a thickness of 100 Å. In a display apparatus of Embodiment 3, a light-receiving device did not include an optical auxiliary layer, and a first layer of an active layer had a thickness of 300 Å, and a second layer of the active layer had a thickness of 100 Å. In a display apparatus of Embodiment 4, a light-receiving device did not include an optical auxiliary layer, a first layer of an active layer had a thickness of 350 Å, and a second layer of the active layer had a thickness of 100 Å.

Referring to FIG. 7, it is found that the light-receiving devices of Embodiment 1 to Embodiment 4 and the light-receiving device of Comparative Example 1 have an absorption center wavelength of about 530±50 nm. That is, it is found that the light-receiving devices of Embodiment 1 to Embodiment 4 and the light-receiving device of Comparative Example 1 may detect green light. On the other hand, it is found that the light-receiving device of Comparative Example 2 has an absorption center wavelength of 480±50 nm, and the light-receiving device of Comparative Example 3 has an absorption center wavelength of 450±50 nm. That is, it is found that the light-receiving devices of Comparative Example 2 and Comparative Example 3 may mainly detect light having a short wavelength such as blue light.

Accordingly, it is found that, when a light-receiving device does not include an optical auxiliary layer and a thickness of a first layer of an active layer is not sufficient, light that may be mainly detected by the light-receiving device moves to light having a short wavelength. As described above, when a light-receiving device absorbs light having a short wavelength, there may be a limit to information that may be read from a user or an object may not be accurately recognized. For example, referring to FIG. 7, the display apparatus of Comparative Example 2 has an EQE of 33% for light having a wavelength of 530 nm, and the display apparatus of Comparative Example 3 has an EQE of 13% for light having a wavelength of 530 nm. That is, simply removing an optical auxiliary layer from a light-receiving device to increase a resolution of the display apparatus 1 (see FIG. 5) may relatively reduce sensing sensitivity. However, in order to implement a high-resolution product, it may be

inevitable to remove an optical auxiliary layer form a light-receiving device. To solve this problem, a display apparatus according to embodiments may have high EQQ, despite not locating an optical auxiliary layer, by increasing a thickness of a layer of an active layer.

For example, referring to FIG. 7, the display apparatus of Embodiment 1 has an EQE of 50% for light having a wavelength of 530 nm, and the display apparatus of Embodiment 2 has an EQE of 73% for light having a wavelength of 530 nm. The display apparatus of Embodiment 3 has an EQE of 90% for light having a wavelength of 530 nm, and the display apparatus of Embodiment 4 has an EQE of 100% for light having a wavelength of 530 nm. That is, it is found that the display apparatuses of Embodiment 1 to Embodiment 4 have a high absorption efficiency and high EQE for light having a wavelength of 530 nm, even though an optical auxiliary layer is not located. In particular, it is found that EQE increases as a thickness of a first layer of an active layer increases, which may mean that sensing sensitivity of a light-receiving device increases as a thickness of a first layer of an active layer increases.

In addition, it is found that, in the display apparatuses of Embodiment 1 to Embodiment 4, as a first layer of an active layer has a certain thickness or more, a resonance phenomenon of a light-receiving device may be neutralized, and light in a wider wavelength band may be absorbed by using light absorption characteristics of a material of the first layer. For example, it is found that the display apparatuses of Embodiment 1 to Embodiment 4 have high EQE in a wavelength band of 530 nm and may absorb all light in a wavelength band of 440 nm to 560 nm with high efficiency. In other words, the display apparatuses of Embodiment 1 to Embodiment 4 may detect light in a wide wavelength band, and thus, may have excellent sensing sensitivity, compared to a case of detecting light in a narrow wavelength band as in the display apparatus of Comparative Example 1.

In conclusion, as in a display apparatus according to some embodiments, when a light-receiving device does not include an optical auxiliary layer and a first layer of an active layer has a sufficient thickness, a high-resolution image may be implemented and sensing sensitivity may be relatively improved.

As described above, in a display apparatus according to some embodiments, a light-receiving device may absorb light in a wider wavelength band, thereby relatively improving sensing sensitivity. The above effects are only an example, and the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims, and their equivalents.

What is claimed is:

1. A display apparatus comprising:
a substrate comprising an emission area and a sensing area;
a light-emitting device on the substrate to correspond to the emission area; and
a light-receiving device on the substrate to correspond to the sensing area,
wherein the light-emitting device comprises a pixel electrode, an emission layer on the pixel electrode, and a counter electrode on the emission layer, and
the light-receiving device comprises a sensing electrode, an active layer on the sensing electrode, and the counter electrode on the active layer,
wherein the active layer comprises a first layer comprising an electron donor material and a second layer on the first layer and comprising an electron acceptor material,
wherein, in a thickness direction of the substrate, a thickness of the first layer is at least a thickness of the second layer.

2. The display apparatus of claim 1, wherein
the first layer comprises a p-type organic semiconductor, and
the second layer comprises an n-type organic semiconductor.

3. The display apparatus of claim 1, wherein the thickness of the first layer is inversely proportional to an absorbance of the first layer.

4. The display apparatus of claim 3, wherein a thickness of the first layer is in an range of 200 Å to 600 Å.

5. The display apparatus of claim 3, wherein the absorbance of the first layer is in a range of 0.2 to 0.6.

6. The display apparatus of claim 3, wherein the thickness of the first layer satisfies Equation 1,
$$T = 120 / a , \qquad Equation 1$$
where T is the thickness of the first layer and a is the absorbance of the first layer.

7. The display apparatus of claim 1, further comprising a common layer between the pixel electrode and the emission layer and between the sensing electrode and the active layer,
wherein the common layer comprises at least one of a hole injection layer or a hole transport layer.

8. The display apparatus of claim 7, wherein the light-emitting device further comprises an optical auxiliary layer between the common layer and the emission layer, wherein a bottom surface of the emission layer directly contacts a top surface of the optical auxiliary layer.

9. The display apparatus of claim 8, wherein the optical auxiliary layer is patterned to have a different thickness for each light-emitting device.

10. The display apparatus of claim 7, wherein a bottom surface of the active layer directly contacts a top surface of the common layer.

11. The display apparatus of claim 1, wherein
the pixel electrode and the sensing electrode are reflective electrodes, and
the counter electrode is a transflective electrode or a transmissive electrode.

12. The display apparatus of claim 11, wherein
the light-emitting device has a front resonance structure, and
the light-receiving device has a non-resonance structure in which a resonance phenomenon is neutralized.

13. A display apparatus comprising:
a substrate;
a light-emitting device on the substrate and comprising a pixel electrode, an emission layer on the pixel electrode, and a counter electrode on the emission layer; and
a light-receiving device on the substrate and comprising a sensing electrode, an active layer on the sensing electrode, and the counter electrode on the active layer,
wherein the light-emitting device and the light-receiving device further include a common layer between the pixel electrode and the emission layer and between the sensing electrode and the active layer,
wherein a bottom surface of the active layer and a top surface of the common layer directly contact each other.

14. The display apparatus of claim 13, wherein the common layer comprises at least one of a hole injection layer or a hole transport layer,
wherein the common layer is integrally formed over an entire surface of the substrate.

15. The display apparatus of claim 13, wherein the light-emitting device further comprises an optical auxiliary layer between the common layer and the emission layer,
wherein a bottom surface of the emission layer directly contacts the optical auxiliary layer.

16. The display apparatus of claim 15, wherein the optical auxiliary layer is patterned only in the light-emitting device and is not located in the light-receiving device.

17. The display apparatus of claim 13, wherein the active layer comprises a first layer comprising an electron donor layer and a second layer on the first layer and comprising an electron acceptor material,
wherein, in a thickness direction of the substrate, a thickness of the first layer is at least a thickness of the second layer.

18. The display apparatus of claim 17, wherein
the first layer comprises a p-type organic semiconductor, and
the second layer comprises an n-type organic semiconductor.

19. The display apparatus of claim 17, wherein the thickness of the first layer is inversely proportional to an absorbance of the first layer.

20. The display apparatus of claim 13, wherein
the pixel electrode and the sensing electrode are reflective electrodes, and
the counter electrode is a transflective electrode or a transmissive electrode.
